(19) United States
(12) Patent Application Publication
(10) Pub. No.: US 2008/0057652 A1
(43) Pub. Date: Mar. 6, 2008

(54) ION IMPLANTATION METHOD OF SEMICONDUCTOR DEVICE

(76) Inventor: Mun-Sub Hwang, Seoul (KR)

Correspondence Address: SHERR & NOURSE, PLLC, 620 HERNDON PARKWAY, SUITE 200, HERNDON, VA, 20170, US

(21) Appl. No.: 11/844,529

(22) Filed: Aug. 24, 2007

(30) Foreign Application Priority Data
Aug. 29, 2006 (KR) 10-2006-0082460

(51) Int. Cl. H01L 21/8234

(52) U.S. Cl. 438/276; 257/E21.616

(57) ABSTRACT

Embodiments relate to an ion implantation method wherein a semiconductor substrate is divided into a core region, a high voltage region, and an I/O region. The core region and the I/O region are divided into a PMOS transistor region for forming PMOS transistors and an NMOS transistor region for forming NMOS transistors. The ion implantation method includes performing a first ion implantation process employing a first process condition on the NMOS transistor region of the substrate using a first mask, thus setting threshold voltages for the NMOS transistor region of the I/O region and for the high voltage region at the same time. A second ion implantation process employs a second process condition on the NMOS transistor region of the substrate using a second mask, thus setting a threshold voltage for the core region. A third ion implantation process employs a third process condition on the PMOS transistor region of the substrate using a third mask, thus setting threshold voltages for the PMOS transistor regions of the core and the I/O region.

The present application claims priority under 35 U.S.C. 119 to Korean Patent Application No. 10-2006-0082460 (filed on Aug. 29, 2006), which is hereby incorporated by reference in its entirety.

### BACKGROUND

The areal density of semiconductor devices is being continuously increased to save manufacturing costs, decrease power consumption, and increase operating speed. As a result, it has been necessary to use low voltage devices in a core logic area, high voltage devices in analog and I/O parts, and system-on-chip (SoC) designs in which various core ICs and memory are mounted in one chip.

In SoC products, a variety of process techniques, such as the use of a multi-threshold voltage process or high voltage I/O devices for power control in analog or RF devices, may be used to perform various functions. To use a multi-threshold voltage process, a larger number of process steps are required because a medium threshold voltage (hereinafter, simply referred to as “Vₜ”) transistor and a native transistor must be used, as compared to a logic process employing only core or I/O Vₜ. In other words, a core region, a high voltage region and an I/O region may all be defined in a multi-threshold process.

A plurality of PMOS (p-channel metal oxide semiconductor field effect transistor) transistors or a plurality of NMOS (n-channel metal oxide semiconductor field effect transistor) transistors may be formed in each region. Each transistor may be formed by, for example, sequentially performing an ion implantation process for a Vₜ setting, a gate formation process, a Lightly Doped Drain (LDD) formation process, and a source/drain process.

In particular, the ion implantation process for a Vₜ setting is described below in detail. An ion implantation process may be performed on an NMOS transistor region and a PMOS transistor region. A first ion implantation process may be carried out on the substrate of the NMOS transistor region and a second ion implantation process may be performed on the core region to set Vₜ for a core. A third ion implantation process may be performed on the I/O region to set Vₜ for I/O. A fourth ion implantation process may be performed on the high voltage region to set Vₜ for high voltage devices. A fifth ion implantation process may then be performed on the substrate of the PMOS transistor region and a sixth ion implantation process is performed on the core region to set Vₜ for a core. A seventh ion implantation process is performed on the I/O region to set Vₜ for I/O.

Thus, in order to set Vₜ in the NMOS transistor region of the core region, the high voltage region, and the I/O region, four ion implantation processes are required. In order to set Vₜ in the PMOS transistor region of the core region, the high voltage region, and the I/O region, three ion implantation processes are required. The process conditions for ion implantation, such as dopant type, energy, and dose, can vary depending on the NMOS transistor or the PMOS transistor, and the core region, the high voltage region, and the I/O region.

As described above, an ion implantation process for setting Vₜ may require a large number of process steps and an additional mask for each process. Accordingly, the mask manufacturing costs are increased. Process time may be increased and the device unit cost may rise with each process step.

### SUMMARY

Embodiments relate to an ion implantation method in which process conditions can be optimized to greatly reduce the number of process steps, thus shortening process time and providing cost savings. Embodiments relate to an ion implantation method wherein a semiconductor substrate is divided into a core region, a high voltage region, and an I/O region. The core region and the I/O region are divided into a PMOS transistor region for forming PMOS transistors and an NMOS transistor region for forming NMOS transistors. The ion implantation method includes performing a first ion implantation process employing a first process condition on the NMOS transistor region of the substrate using a first mask, thus setting threshold voltages for the NMOS transistor region of the I/O region and for the high voltage region at the same time. A second ion implantation process employs a second process condition on the NMOS transistor region of the substrate using a second mask, thus setting a threshold voltage for the core region. A third ion implantation process employs a third process condition on the PMOS transistor region of the substrate using a third mask, thus setting threshold voltages for the PMOS transistor regions of the core and the I/O region.

Embodiments relate to an ion implantation method for a semiconductor substrate which is divided into a core region, a high voltage region, and an I/O region. The core region and the I/O region are divided into a PMOS transistor region and an NMOS transistor region. The ion implantation method includes performing a first ion implantation process employing a first process condition on the PMOS transistor region using a first mask, thereby setting threshold voltages for the PMOS transistor regions of the core and the I/O region. A second ion implantation process employs a second process condition on the NMOS transistor region using a second mask, thereby setting threshold voltages for the NMOS transistor region in the I/O region and for the high voltage region at the same time. A third ion implantation process employs a third process condition on the NMOS transistor region using a third mask, thus setting a threshold voltage for the NMOS transistor region of the core region.

### DRAWINGS

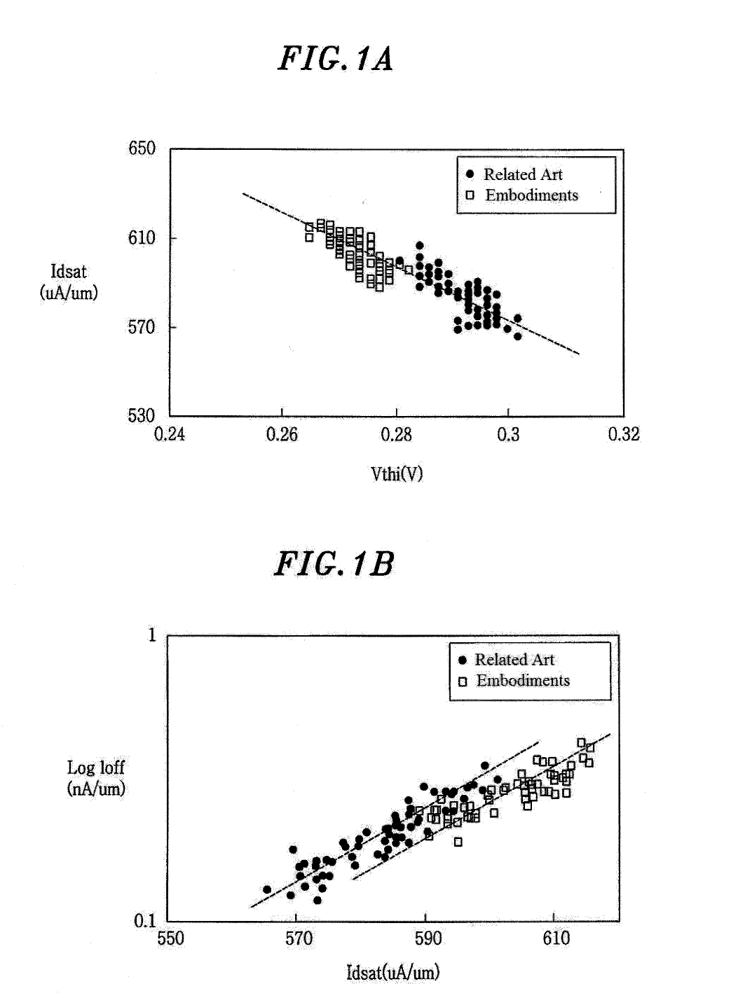

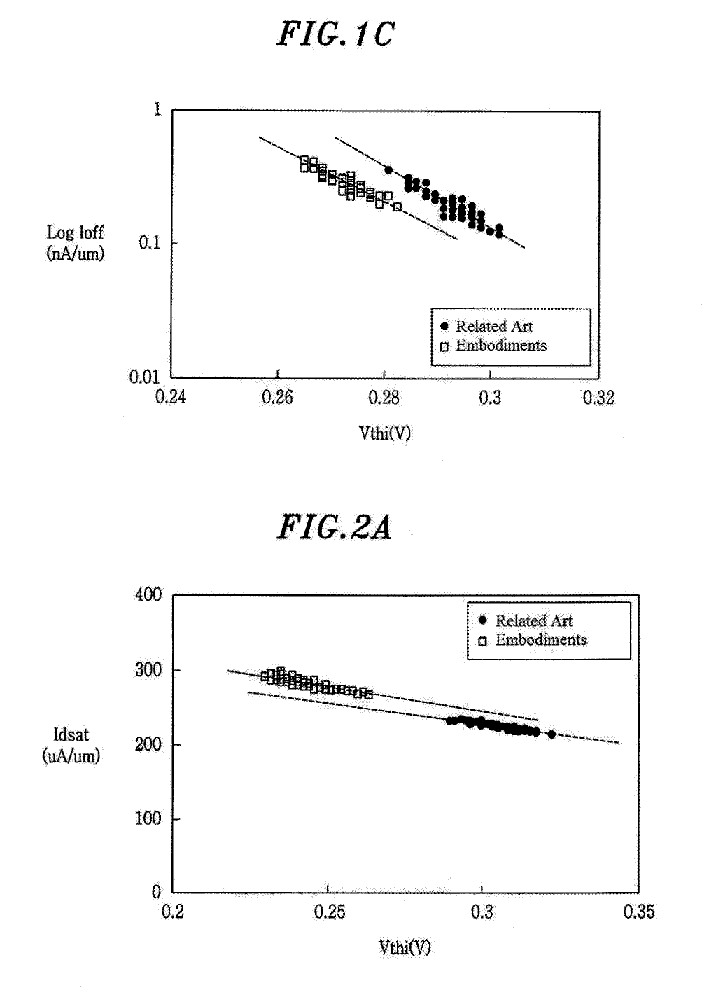

Example FIGS. 1A to 1C are graphs illustrating electrical characteristics of an NMOS transistor in accordance with embodiments.

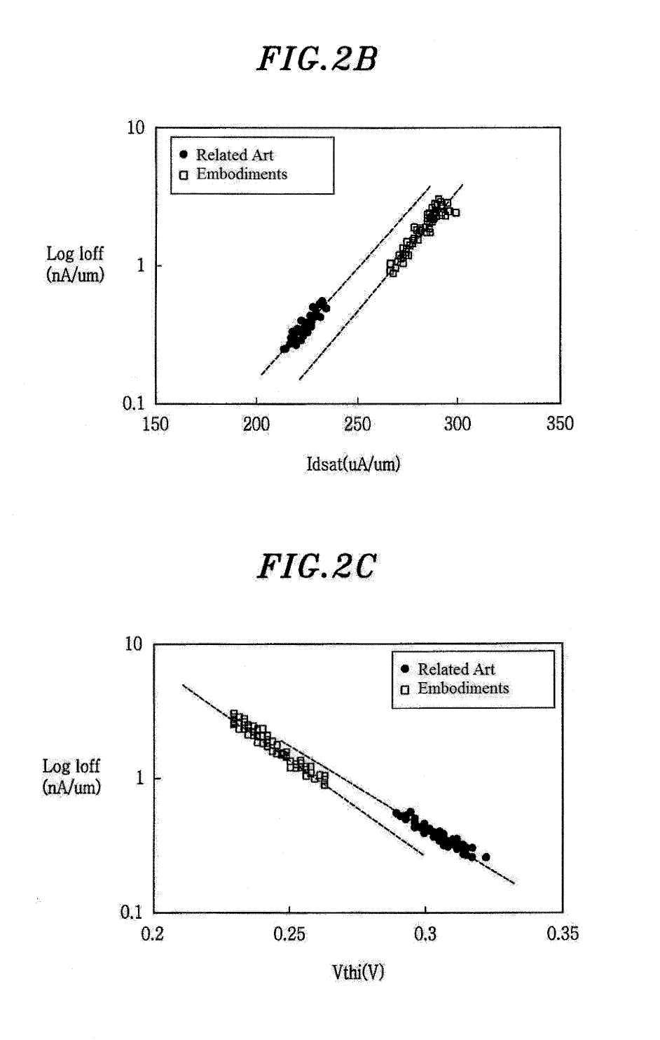

Example FIGS. 2A to 2C are graphs illustrating electrical characteristics of a PMOS transistor in accordance with embodiments.

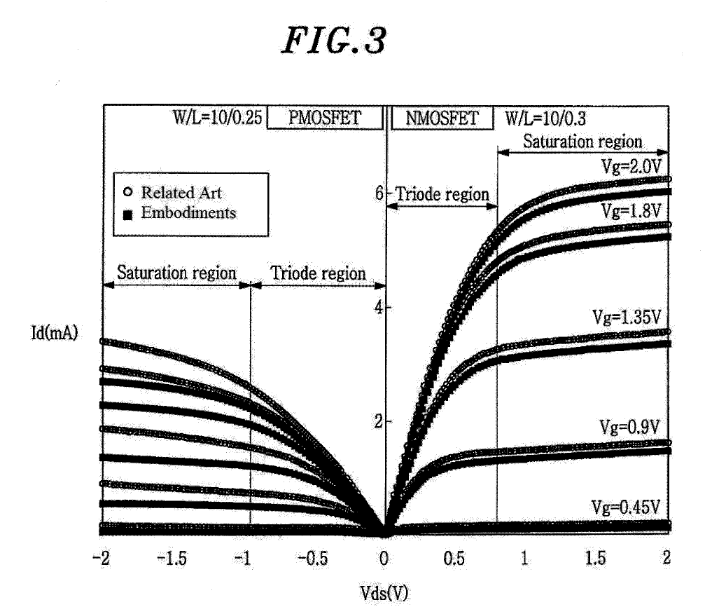

Example FIG. 3 is a graph showing driving current (I_{d}) curves depending on applied voltages V_{ds} of the NMOS transistor and the PMOS transistor in accordance with embodiments.

### DESCRIPTION

Embodiments may save time and reduce costs by significantly streamlining an ion implantation process. According to embodiments, ion implantation processes may be performed twice on an NMOS transistor of a core region, a high voltage region, and an I/O region. An ion implantation process may be performed once on a PMOS transistor of the core region, the high voltage region, and the I/O region. Consequently, a total of three ion implantation processes are performed. This is four fewer process steps compared with the seven ion implantation processes in the related art. Accordingly, the costs of forming masks may be reduced. Process time may be significantly reduced because only three ion implantation processes are performed.

A substrate is prepared in which a core region, a high voltage region, and an I/O region are defined. The core region and the I/O region are divided into a PMOS transistor region and an NMOS transistor region in which a plurality of PMOS transistors and a plurality of NMOS transistors will be formed, respectively.

A first ion implantation process employing a first process condition may be first performed on the NMOS transistor region of the substrate by using a first mask, thus setting Vₜ for I/O and Vₜ for high voltage devices at the same time. The first process condition may include, for example, 11B+ dopant, a dose between 2.5×10¹² and 4.5×10¹² ion/cm², energy between 18 and 22 KeV, and a tilt of approximately 7 degrees. The first mask may be patterned such that the dopant is implanted into the NMOS transistor region in the I/O region and the high voltage region. Thus, the 11B+ dopant, which has passed through the first mask, is not implanted into the core region.

A second ion implantation process employing a second process condition may be performed on the NMOS transistor region using a second mask, thus setting Vₜ for the core region. The second process condition may include, for example, the 11B+ dopant, a dose between 2.8×10¹² and 4.8×10¹² ion/cm², an energy between 18 and 22 KeV, and a tilt of approximately 7 degrees. The second mask is patterned such that the dopant may be implanted into the NMOS transistor region of the core region. Thus, the 11B+ dopant which has passed through the second mask is not implanted into the I/O region and the high voltage region.

A third ion implantation process employing a third process condition may be performed on the PMOS transistor region on the substrate by using a third mask, thus setting Vₜ for the core region and Vₜ for I/O. The third process condition may include the dopant 75As+, a dose between 8×10¹² and 1×10¹³ ion/cm², energy between 99 and 121 KeV, and a tilt of 7 degrees. The third mask may be patterned such that the dopant is implanted into the PMOS transistor regions of the core and the I/O region. Thus, the 75As+ dopant which has passed through the third mask is not implanted into the high voltage region.

In the above ion implantation method, after ion implantation is performed on the NMOS transistor region, ion implantation is performed on the PMOS transistor region. It is, however, to be noted that ion implantation may be performed on the PMOS transistor region, and thereafter on the NMOS transistor region. In other words, the order of implantation can be reversed between the PMOS and NMOS regions.

Through this ion implantation method, the number of process steps can be reduced significantly compared with the related art. In other words, the seven ion implantation processes of the related art can be substituted by the three ion implantation processes of the embodiments. Accordingly, process time can be shortened and costs reduced. Embodiments may also maximize device characteristics since the mobility is increased by 30% or higher compared with the related art.

In order to verify these effects, the following experiment was carried out. In other words, in order to set Vₜ for the I/O region, a process condition as illustrated Table 1 was used.

TABLE 1

| | Related Art | | Embodiments | |
|---|---|---|---|---|
| | NMOS | PMOS | NMOS | PMOS |
| Well Channel | B | As | B | Skip |
| Implantation | 20 KeV | 110 KeV | 20 KeV | |
| | 7.3 × 10¹² | 9 × 10¹² | 3.5 × 10¹² | |
| CNM/CPM | As | B | Skip | Skip |
| | 110 KeV | 110 KeV | | |
| | 3 × 10¹² | 8.5 × 10¹² | | |

Well channel implantation refers to a process of performing ion implantation on the entire regions including the core region, the high voltage region, and the I/O region of the substrate in the related art CNM/CPM refers to a process of performing ion implantation on the I/O region. Measurements were taken using HP4072, 4156B equipment. The threshold voltage Vₜ, the saturation current I_{dsat}, the leakage current I_{off}, and analog characteristic gm were analyzed.

Example FIGS. 1A to 1C are graphs illustrating electrical characteristics of an NMOS transistor in a semiconductor device in accordance with embodiments. Example FIG. 1A is a graph showing the saturation current with respect to the threshold voltage of the NMOS transistor of embodiments. Example FIG. 1B is a graph showing the leakage current with respect to the saturation current of the NMOS transistor of embodiments. Example FIG. 1C is a graph showing the leakage current with respect to the threshold voltage of the NMOS transistor of embodiments.

It can be seen that the saturation current I_{dsat} in embodiments increases with respect to the threshold voltage Vₜ compared with the related art, as illustrated in example FIG. 1A. The leakage current in embodiments decreases with respect to the saturation current and the threshold voltage compared with the related art, as illustrated in example FIGS. 1B and 1C. In other words, according to embodiments, the leakage current may be reduced by about 20% and 42% with respect to the saturation current and the threshold voltage, respectively, compared with the related art. Accordingly, it can be seen that the mobility of the semiconductor device of embodiments is maximized.

Example FIGS. 2A to 2C are graphs illustrating electrical characteristics of a PMOS transistor in accordance with embodiments. Example FIG. 2A is a graph showing the saturation current with respect to the threshold voltage of the PMOS transistor of embodiments. Example FIG. 2B is a graph showing the leakage current with respect to the saturation current of the PMOS transistor of embodiments. Example FIG. 2C is a graph showing the leakage current with respect to the threshold voltage of the PMOS transistor of embodiments.

Even in the case of the PMOS transistor, the leakage current in embodiments may be reduced by about 34% and 53% with respect to the saturation current and the threshold voltage, respectively, compared with the related art in the same manner as the NMOS transistor. Accordingly, it can be seen that the mobility of the semiconductor device of embodiments is maximized.

Example FIG. 3 is a graph showing driving current (I_{d}) curves depending on application voltages V_{ds} of the NMOS transistor and the PMOS transistor in accordance with embodiments. From example FIG. 3, it can be seen that the driving current of embodiments is increased with respect to the PMOS transistor and the NMOS transistor compared with the related art.

As described above, according to embodiments, process conditions for an ion implantation process are optimized. Accordingly, process steps may be reduced, processing time may be shortened, and costs can be reduced. Furthermore, in accordance with embodiments, the mobility may be maximized compared with the related art.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
preparing a semiconductor substrate, wherein the substrate is divided into a core region, a high voltage region, and an I/O region, and the core region and the I/O region are divided into a PMOS transistor region and an NMOS transistor region;
performing a first ion implantation process employing a first process condition on the NMOS transistor region of the substrate using a first mask, thereby setting threshold voltages for the NMOS transistor region in the I/O region and in the high voltage region simultaneously;
performing a second ion implantation process employing a second process condition on the NMOS transistor region of the substrate using a second mask, thereby setting a threshold voltage for the NMOS transistor region of the core region; and
performing a third ion implantation process employing a third process condition on the PMOS transistor region of the substrate using a third mask, thereby setting threshold voltages for the PMOS transistor regions of the core and the I/O region.

2. The method of claim 1, wherein the first process condition comprises 11B+ dopant.

3. The method of claim 2, wherein the first process condition comprises a dopant dose between approximately 2.5×10¹² and 4.5×10¹² ion/cm².

4. The method of claim 2, wherein the first process condition comprises ion implantation energy between approximately 18 and 22 KeV, at a tilt of approximately 7 degrees.

5. The method of claim 1, wherein the first mask is patterned such that a dopant is implanted into the NMOS transistor region of the I/O region and the high voltage region.

6. The method of claim 1, wherein the second process condition comprises an 11B+ dopant.

7. The method of claim 6, wherein the second process condition comprises a dopant dose between approximately 2.8×10¹² to 4.8×10¹² ion/cm².

8. The method of claim 6, wherein the second process condition comprises ion implantation energy between approximately 18 and 22 KeV, at a tilt of approximately 7 degrees.

9. The method of claim 1, wherein the second mask is patterned such that a dopant is implanted into the NMOS transistor region of the core region.

10. The method of claim 1, wherein the third process condition comprises 75As+ dopant.

11. The method of claim 10, wherein the third process condition comprises a dopant dose between approximately 8×10¹² and 1×10¹³ ion/cm².

12. The method of claim 10, wherein the third process condition comprises an ion implantation energy between approximately 99 and 121 KeV at a tilt of approximately 7 degrees.

13. The method of claim 1, wherein the third mask is patterned such that a dopant is implanted into the PMOS transistor regions of the core and the I/O region.

14. A method comprising:
preparing a semiconductor substrate, wherein the substrate is divided into a core region, a high voltage region, and an I/O region, and the core region and the I/O region are divided into a PMOS transistor region and an NMOS transistor region;
performing a first ion implantation process employing a first process condition on the PMOS transistor region of the substrate using a first mask, thereby setting threshold voltages for the PMOS transistor regions in the core and the I/O region;
performing a second ion implantation process employing a second process condition on the NMOS transistor region of the substrate using a second mask, thereby setting threshold voltages for the NMOS transistor region in the I/O region and in the high voltage region simultaneously; and
performing a third ion implantation process employing a third process condition on the NMOS transistor region of the substrate by using a third mask, thereby setting a threshold voltage for the NMOS transistor region in the core region.

15. The method of claim 14, wherein the first process condition comprises 75As+ dopant, a dose between approximately 8×10¹² and 1×10¹³ ion/cm², energy between approximately 99 and 121 KeV, and a tilt of approximately 7 degrees.

16. The method of claim 14, wherein the first mask is patterned such that a dopant is implanted into the PMOS transistor regions of the core and the I/O region.

17. The method of claim 14, wherein the second process condition comprises 11B+ dopant, a dose between approximately 2.5×10¹² and 4.5×10¹² ion/cm², energy between approximately 18 and 22 KeV, and a tilt of approximately 7 degrees.

18. The method of claim 14, wherein the second mask is patterned such that a dopant is implanted into the NMOS transistor region of the I/O region and the high voltage region.

19. The method of claim 14, wherein the third process condition comprises an 11B+ dopant, a dose between approximately 2.8×10¹² to 4.8×10¹² ion/cm², energy between approximately 18 and 22 KeV, and a tilt of approximately 7 degrees.

20. The method of claim 14, wherein the third mask is patterned such that a dopant is implanted into the NMOS transistor region of the core region.
